(19) United States
(12) Patent Application Publication
(10) Pub. No.: US 2016/0020783 A1
(43) Pub. Date: Jan. 21, 2016

(54) Low Density Parity Check Decoder With Relative Indexing

(71) Applicant: LSI Corporation, San Jose, CA (US)

(72) Inventors: Shaohua Yang, San Jose, CA (US); Shu Li, San Jose, CA (US); Dan Liu, Shanghai (CN); Qi Zuo, Shanghai (CN)

(21) Appl. No.: 14/334,125

(22) Filed: Jul. 17, 2014

(51) Int. Cl. H03M 13/11; G11B 20/10; G11B 20/18

(52) U.S. Cl. CPC H03M 13/114; H03M 13/116; G11B 20/1833; G11B 20/10037; G11B 2020/185

(57) ABSTRACT

An apparatus for low density parity check decoding includes a variable node processor and a check node processor. The variable node processor is operable to generate variable node to check node messages and to update variable node values based on check node to variable node messages. The check node processor is operable to generate the check node to variable node messages based on the variable node to check node messages. The variable node processor and the check node processor comprise a quasi-cyclic decoder with relative indexes that refer to non-zero circulants.

### FIELD OF THE INVENTION

Various embodiments of the present invention provide systems and methods for processing data, and more particularly to systems and methods for a low density parity check decoder with relative indexing of non-zero circulants.

### BACKGROUND

Various data processing systems have been developed including storage systems, cellular telephone systems, and radio transmission systems. In such systems data is transferred from a sender to a receiver via some medium. For example, in a storage system, data is sent from a sender (i.e., a write function) to a receiver (i.e., a read function) via a storage medium. As information is stored and transmitted in the form of digital data, errors are introduced that, if not corrected, can corrupt the data and render the information unusable. The effectiveness of any transfer is impacted by any losses in data caused by various factors. Many types of error checking systems have been developed to detect and correct errors in digital data. For example, parity bits can be added to groups of data bits, ensuring that the groups of data bits (including the parity bits) have either even or odd numbers of ones. The parity bits can be used in error correction systems, including in Low Density Parity Check (LDPC) decoders.

### BRIEF SUMMARY

Embodiments of the present invention provide a quasi-cyclic low density parity check decoder including a variable node processor and a check node processor. The variable node processor is operable to generate variable node to check node messages and to update variable node values based on check node to variable node messages. The check node processor is operable to generate the check node to variable node messages based on the variable node to check node messages. The variable node processor and the check node processor use relative indexes that refer to non-zero circulants in the parity check matrix.

This summary provides only a general outline of some embodiments according to the present invention. Many other embodiments of the present invention will become more fully apparent from the following detailed description, the appended claims and the accompanying drawings.

### BRIEF DESCRIPTION OF THE DRAWINGS

A further understanding of the various embodiments of the present invention may be realized by reference to the figures which are described in remaining portions of the specification. In the figures, like reference numerals are used throughout several figures to refer to similar components.

FIG. 1 depicts a storage system including a read channel with a low density parity check decoder with relative indexing in accordance with some embodiments of the present invention;

FIG. 2 depicts a wireless communication system including a receiver with a low density parity check decoder with relative indexing in accordance with some embodiments of the present invention;

FIG. 3 depicts another storage system including a data processing circuit having a low density parity check decoder with relative indexing in accordance with some embodiments of the present invention;

FIG. 4 depicts a read channel with a low density parity check decoder with relative indexing in accordance with some embodiments of the present invention;

FIG. 5 depicts a Tanner graph of a simplified portion of a low density parity check code that can be decoded in a low density parity check decoder with relative indexing in accordance with some embodiments of the present invention;

FIG. 6 depicts a low density parity check non-layer decoder with relative indexing in accordance with some embodiments of the present invention;

FIG. 7 depicts a low density parity check layer decoder with relative indexing in accordance with some embodiments of the present invention;

FIG. 8 depicts an H matrix with lettered non-zero circulant sub-matrices which can be decoded by a quasi-cyclic low density parity check layer decoder with relative indexing in accordance with some embodiments of the present invention;

FIG. 9 depicts an H matrix with lettered non-zero circulant sub-matrices which can be decoded by a quasi-cyclic low density parity check layer decoder with relative indexing, and a corresponding weight matrix indicating non-zero circulant locations, wherein the non-zero circulant index is used for the relative index, in accordance with some embodiments of the present invention;

FIG. 10 depicts an H matrix and corresponding decoding instruction set which can used for decoding in a quasi-cyclic low density parity check layer decoder with relative indexing, wherein the circulant decoding order is used for the relative index, in accordance with some embodiments of the present invention;

FIG. 11 depicts a low density parity check layer decoder with targeted symbol flipping in accordance with some embodiments of the present invention;

FIG. 12 is a flow diagram of an operation to decode data in a low density parity check layer decoder with relative indexing in accordance with some embodiments of the present invention.

### DETAILED DESCRIPTION OF THE INVENTION

Embodiments of the present invention are related to a low density parity check decoder with relative indexing of non-zero circulants. In some embodiments, the low density parity check decoder is a min-sum based decoder which performs check node processing by determining the minimum or lowest scaled variable node to check node (V2C) message (min₁), the next minimum called variable node to check node message (min₂), and the index idx of min₁. Rather than using the column index of the H-matrix for the index of min₁, the index idx is relative only to non-zero circulants, referring only to non-zero circulants, and disregards the zero-circulants in each row of the H-matrix. By indexing only non-zero circulants, the index values can be stored with fewer bits, reducing the number of flip-flops or other storage devices in the decoder, which reduces the size of the decoder and the power consumption.

The instruction set used by the decoder to read instructions cycle by cycle to carry out the decoding is also adapted to support indexing of non-zero circulants. This, in turn, simplifies retry features such as, but not limited to, targeted symbol flipping, because it is not necessary to exhaustively read the entire instruction set and compare content to identify targeted symbol flipping candidates. By indexing only non-zero circulants, a targeted symbol flipping operation can retrieve information about candidate symbols in a single step. Latency and power consumption in retry mode are thus reduced.

In some embodiments, non-zero circulants in a row or layer are grouped, further reducing the stored bits in the instruction set. For example, with Rw non-zero circulants in a layer, organized in N groups, the non-zero circulants in each of the N groups are indexed separately. In the instruction set, the relative index uses ceil (log 2(Rw/N)) bits instead of log 2(Rw) bits. After the grouped index is read, the group index is appended to obtain the full relative index.

Low density parity check technology is applicable to transmission of information over virtually any channel or storage of information on virtually any media. Transmission applications include, but are not limited to, optical fiber, radio frequency channels, wired or wireless local area networks, digital subscriber line technologies, wireless cellular, Ethernet over any medium such as copper or optical fiber, cable channels such as cable television, and Earth-satellite communications. Storage applications include, but are not limited to, hard disk drives, compact disks, digital video disks, magnetic tapes and memory devices such as DRAM, NAND flash, NOR flash, other non-volatile memories and solid state drives.

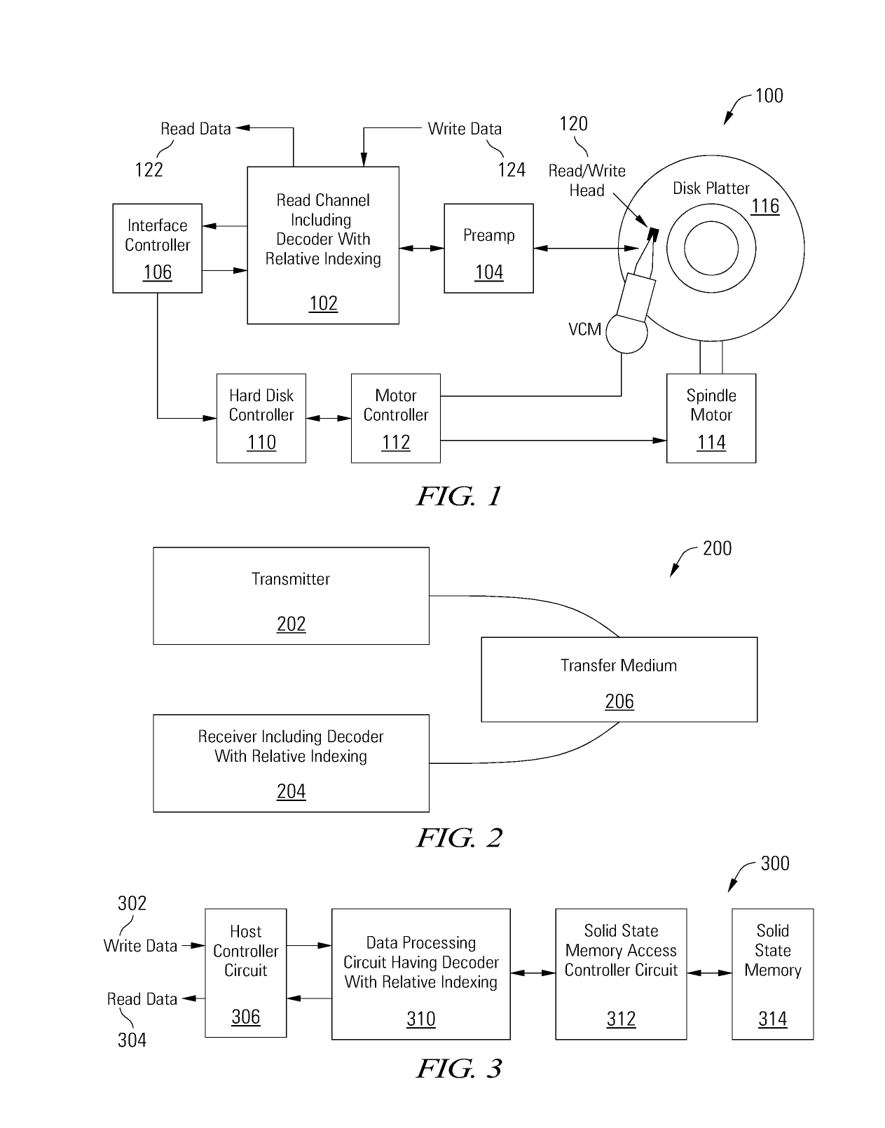

Although the low density parity check decoder with relative indexing disclosed herein is not limited to any particular application, several example applications are disclosed in FIGS. 1-4 that benefit from embodiments of the present invention. Turning to FIG. 1, a storage system 100 is illustrated as an example application of a low density parity check decoder with relative indexing in accordance with some embodiments of the present invention. The storage system 100 includes a read channel circuit 102 with an adaptive IIR notch filter-based narrowband interference detection and removal circuit in accordance with one or more embodiments of the present invention. Storage system 100 may be, for example, a hard disk drive. Storage system 100 also includes a preamplifier 104, an interface controller 106, a hard disk controller 110, a motor controller 112, a spindle motor 114, a disk platter 116, and a read/write head assembly 120. Interface controller 106 controls addressing and timing of data to/from disk platter 116. The data on disk platter 116 consists of groups of magnetic signals that may be detected by read/write head assembly 120 when the assembly is properly positioned over disk platter 116. In one embodiment, disk platter 116 includes magnetic signals recorded in accordance with either a longitudinal or a perpendicular recording scheme.

In a typical read operation, read/write head assembly 120 is accurately positioned by motor controller 112 over a desired data track on disk platter 116. Motor controller 112 both positions read/write head assembly 120 in relation to disk platter 116 and drives spindle motor 114 by moving read/write head assembly 120 to the proper data track on disk platter 116 under the direction of hard disk controller 110. Spindle motor 114 spins disk platter 116 at a determined spin rate (RPMs). Once read/write head assembly 120 is positioned adjacent the proper data track, magnetic signals representing data on disk platter 116 are sensed by read/write head assembly 120 as disk platter 116 is rotated by spindle motor 114. The sensed magnetic signals are provided as a continuous, minute analog signal representative of the magnetic data on disk platter 116. This minute analog signal is transferred from read/write head assembly 120 to read channel circuit 102 via preamplifier 104. Preamplifier 104 is operable to amplify the minute analog signals accessed from disk platter 116. In turn, read channel circuit 102 digitizes and decodes the received analog signal to recreate the information originally written to disk platter 116. This data is provided as read data 122 to a receiving circuit. While processing the read data, read channel circuit 102 decodes the data using a low density parity check decoder with relative indexing. A write operation is substantially the opposite of the preceding read operation with write data 124 being provided to read channel circuit 102.

It should be noted that storage system 100 can be integrated into a larger storage system such as, for example, a RAID (redundant array of inexpensive disks or redundant array of independent disks) based storage system. Such a RAID storage system increases stability and reliability through redundancy, combining multiple disks as a logical unit. Data may be spread across a number of disks included in the RAID storage system according to a variety of algorithms and accessed by an operating system as if it were a single disk. For example, data may be mirrored to multiple disks in the RAID storage system, or may be sliced and distributed across multiple disks in a number of techniques. If a small number of disks in the RAID storage system fail or become unavailable, error correction techniques may be used to recreate the missing data based on the remaining portions of the data from the other disks in the RAID storage system. The disks in the RAID storage system may be, but are not limited to, individual storage systems such storage system 100, and may be located in close proximity to each other or distributed more widely for increased security. In a write operation, write data is provided to a controller, which stores the write data across the disks, for example by mirroring or by striping the write data. In a read operation, the controller retrieves the data from the disks. The controller then yields the resulting read data as if the RAID storage system were a single disk.

In addition, it should be noted that storage system 100 can be modified to include solid state memory that is used to store data in addition to the storage offered by disk platter 116. This solid state memory may be used in parallel to disk platter 116 to provide additional storage. In such a case, the solid state memory receives and provides information directly to read channel circuit 102. Alternatively, the solid state memory can be used as a cache where it offers faster access time than that offered by disk platter 116. In such a case, the solid state memory can be disposed between interface controller 106 and read channel circuit 102 where it operates as a pass through to disk platter 116 when requested data is not available in the solid state memory or when the solid state memory does not have sufficient storage to hold a newly written data set. Based upon the disclosure provided herein, one of ordinary skill in the art will recognize a variety of storage systems including both disk platter 116 and a solid state memory.

Turning to FIG. 2, a wireless communication system 200 or data transmission device including a transmitter 202 and receiver 204 with a low density parity check decoder with relative indexing is shown in accordance with some embodiments of the present invention. The transmitter 202 is operable to transmit data via a transfer medium 206 as is known in the art. The encoded data is received from transfer medium 206 by receiver 204. Receiver 204 incorporates a low density parity check decoder with relative indexing to decode and correct errors in the received data.

Turning to FIG. 14, another storage system 300 is shown that includes a data processing circuit 310 having a low density parity check decoder with relative indexing in accordance with one or more embodiments of the present invention. A host controller circuit 306 receives data to be stored (i.e., write data 302). This data is provided to data processing circuit 310 where it is encoded, adding parity bits. The data to be written is provided to a solid state memory access controller circuit 312. Solid state memory access controller circuit 312 can be any circuit known in the art that is capable of controlling access to and from a solid state memory. Solid state memory access controller circuit 312 formats the received encoded data for transfer to a solid state memory 314. Solid state memory 314 can be any solid state memory known in the art. In some embodiments of the present invention, solid state memory 314 is a flash memory. Later, when the previously written data is to be accessed from solid state memory 314, solid state memory access controller circuit 312 requests the data from solid state memory 314 and provides the requested data to data processing circuit 310. In turn, data processing circuit 310 decodes the data with a low density parity check decoder with relative indexing. The resulting data are provided to host controller circuit 306 where the data is passed on as read data 304.

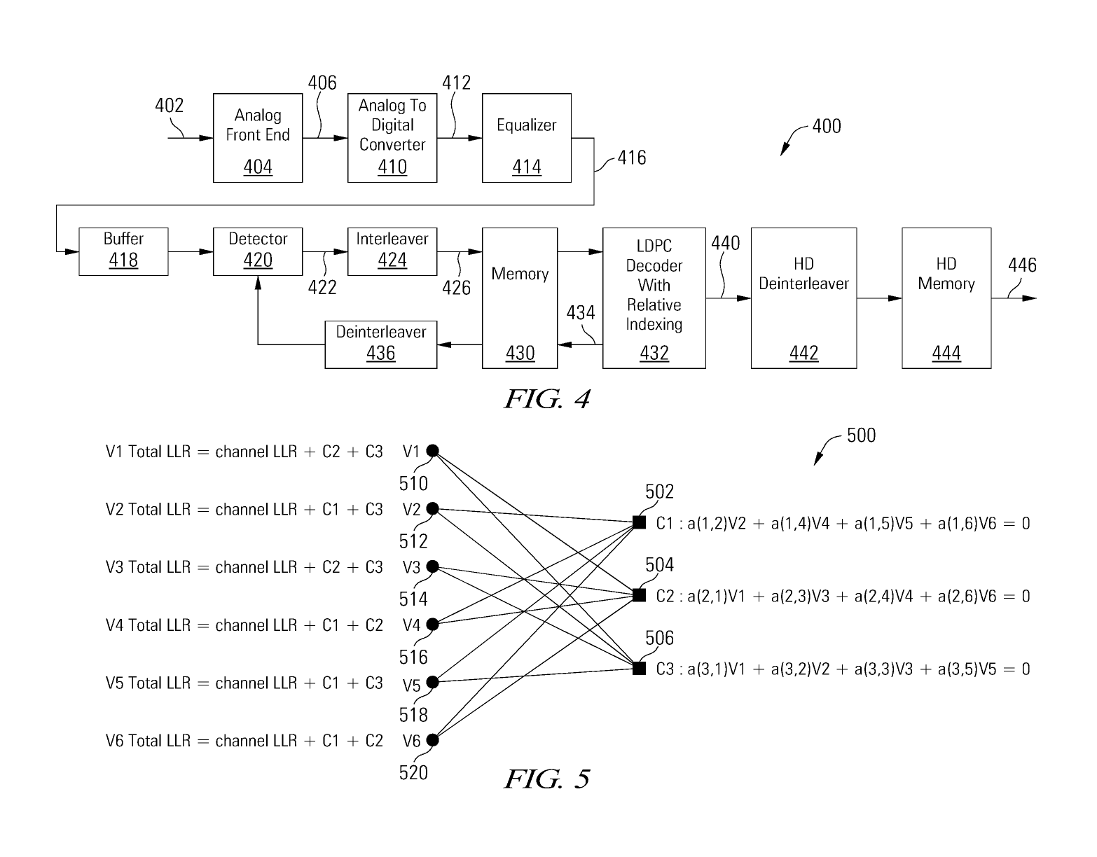

Turning to FIG. 4, a read channel 400 including a low density parity check decoder 432 with relative indexing is used to process an analog signal 402 and to retrieve user data bits from the analog signal 402 without errors. In some cases, analog signal 402 is derived from a read/write head assembly in a magnetic storage medium. In other cases, analog signal 402 is derived from a receiver circuit that is operable to receive a signal from a transmission medium. The transmission medium may be wireless or wired such as, but not limited to, cable or optical connectivity. Based upon the disclosure provided herein, one of ordinary skill in the art will recognize a variety of sources from which analog signal 402 may be derived.

The read channel 400 includes an analog front end 404 that receives and processes the analog signal 402. Analog front end 404 may include, but is not limited to, an analog filter and an amplifier circuit as are known in the art. Based upon the disclosure provided herein, one of ordinary skill in the art will recognize a variety of circuitry that may be included as part of analog front end 404. In some cases, the gain of a variable gain amplifier included as part of analog front end 404 may be modifiable, and the cutoff frequency and boost of an analog filter included in analog front end 404 may be modifiable. Analog front end 404 receives and processes the analog signal 402, and provides a processed analog signal 406 to an analog to digital converter 410.

Analog to digital converter 410 converts processed analog signal 406 into a corresponding series of digital samples 412. Analog to digital converter 410 may be any circuit known in the art that is capable of producing digital samples corresponding to an analog input signal. Based upon the disclosure provided herein, one of ordinary skill in the art will recognize a variety of analog to digital converter circuits that may be used in relation to different embodiments of the present invention. In other embodiments, digital data is retrieved directly from a storage device or other source, such as a flash memory. Digital samples 412 are provided to an equalizer 414. Equalizer 414 applies an equalization algorithm to digital samples 412 to yield an equalized output 416. In some embodiments of the present invention, equalizer 414 is a digital finite impulse response filter circuit as is known in the art. Data or codewords contained in equalized output 416 may be stored in a buffer 418 until a data detector 420 is available for processing.

The data detector 420 performs a data detection process on the received input, resulting in a detected output 422. In some embodiments of the present invention, data detector 420 is a Viterbi algorithm data detector circuit, or more particularly in some cases, a maximum a posteriori (MAP) data detector circuit as is known in the art. In these embodiments, the detected output 422 contains log likelihood ratio information about the likelihood that each bit or symbol has a particular value. Based upon the disclosure provided herein, one of ordinary skill in the art will recognize a variety of data detectors that may be used in relation to different embodiments of the present invention. Data detector 420 is started based upon availability of a data set in buffer 418 from equalizer 414 or another source.

The detected output 422 from data detector 420 is provided to an interleaver 424 that protects data against burst errors. Burst errors overwrite localized groups or bunches of bits. Because low density parity check decoders are best suited to correcting errors that are more uniformly distributed, burst errors can overwhelm low density parity check decoders. The interleaver 424 prevents this by interleaving or shuffling the detected output 422 from data detector 420 to yield an interleaved output 426 which is stored in a memory 430. The interleaved output 426 from the memory 430 is provided to a low density parity check decoder 432 with relative indexing which performs parity checks on the interleaved output 426, ensuring that parity constraints established by a low density parity check encoder (not shown) before storage or transmission are satisfied in order to detect and correct any errors that may have occurred in the data during storage or transmission.

Multiple detection and decoding iterations may be performed in the read channel 400, referred to herein as global iterations. (In contrast, local iterations are decoding iterations performed within the low density parity check decoder 432.) To perform a global iteration, log likelihood ratio values 434 from the low density parity check decoder 432 are stored in memory 430, deinterleaved in a deinterleaver 436 to reverse the process applied by interleaver 424, and provided again to the data detector 420 to allow the data detector 420 to repeat the data detection process, aided by the log likelihood ratio values 434 from the low density parity check decoder 432. In this manner, the read channel 400 can perform multiple global iterations, allowing the data detector 420 and low density parity check decoder 432 to converge on the correct data values.

The low density parity check decoder 432 also produces hard decisions 440 about the values of the data bits or symbols contained in the interleaved output 426 of the interleaver 424. For binary data bits, the hard decisions may be represented as 0's and 1's. In a GF(4) low density parity check decoder, the hard decisions may be represented by four Galois Field elements 00, 01, 10 and 11.

The hard decisions 440 from low density parity check decoder 432 are deinterleaved in a hard decision deinterleaver 442, reversing the process applied in interleaver 424, and stored in a hard decision memory 444 before being provided to a user or further processed. For example, the output 446 of the read channel 400 may be further processed to reverse formatting changes applied before storing data in a magnetic storage medium or transmitting the data across a transmission channel.

A low density parity check code is defined by a sparse parity check matrix H of size m×n, where m<n. A code word c of length n satisfies all the m parity check equations defined by H, i.e., cH^{T}=0, where 0 is a zero vector. Low density parity check codes are Shannon capacity approaching as n increases. In addition, low density parity check codes are relatively friendly to highly parallel decoder implementation. In practical applications, structured low density parity check codes may be used to simplify implementation. Some embodiments use a quasi-cyclic low density parity check (QC-LDPC) code, which can be defined by a parity check matrix composed of circulant sub-matrices of size q×q. In a binary case, a circulant matrix (also called a circulant) is an identity matrix in which all rows (or columns) are cyclically shifted by a fixed amount. For example, if q=4, the following binary circulant

$$[ \begin{matrix}0 & 1 & 0 & 0 \\ 0 & 0 & 1 & 0 \\ 0 & 0 & 0 & 1 \\ 1 & 0 & 0 & 0\end{matrix} ] \qquad ( Eq 1 )$$

is an identity matrix cyclically shifted to the right by 1. For a quasi-cyclic low density parity check code, the parity check matrix can be written in the form of a base matrix H_{b}, in the following form:

$${H}_{b} = [ \begin{matrix}{H}_{11} & … & {H}_{1 N} \\ ⋮ & ⋱ & ⋮ \\ {H}_{M 1} & … & {H}_{MN}\end{matrix} ] \qquad ( Eq 2 )$$

where H_{i,j} is either a circulant of size q×q or a zero matrix, and qM=m, qN=n.

Low density parity check codes are also known as graph-based codes with iterative decoding algorithms, which can be visually represented in a Tanner graph 500 as illustrated in FIG. 5. In a low density parity check decoder, multiple parity checks are performed in a number of check nodes (e.g., 502, 504 and 506) for a group of variable nodes (e.g., 510, 512, 514, 516, 518, and 520). The connections (or edges) between variable nodes 510-520 and check nodes 502-506 are selected as the low density parity check code is designed, balancing the strength of the code against the complexity of the decoder required to execute the low density parity check code as data is obtained. The number and placement of parity bits in the group are selected as the low density parity check code is designed. Messages are passed between connected variable nodes 510-520 and check nodes 502-506 in an iterative process, passing beliefs about the values that should appear in variable nodes 510-520 to connected check nodes 502-506. Parity checks are performed in the check nodes 502-506 based on the messages and the results are returned to connected variable nodes 510-520 to update the beliefs if necessary. Low density parity check decoders can be implemented in binary or non-binary fashion. In a binary low density parity check decoder, variable nodes 510-520 contain scalar values based on a group of data and parity bits that are retrieved from a storage device, received by a transmission system or obtained in some other way. Messages in the binary low density parity check decoders are scalar values transmitted as plain-likelihood probability values or log likelihood ratio (LLR) values representing the probability that the sending variable node contains a particular value. In a non-binary low density parity check decoder, variable nodes 510-520 contain symbols from a Galois Field, a finite field GF(p^{k}) that contains a finite number of elements, characterized by size p^{k} where p is a prime number and k is a positive integer. Messages in the non-binary low density parity check decoders are multi-dimensional vectors, generally either plain-likelihood probability vectors or log likelihood ratio vectors.

The connections between variable nodes 510-520 and check nodes 502-506 may be presented in matrix form as follows, where columns represent variable nodes, rows represent check nodes, and a random non-zero element a(i,j) from the Galois Field at the intersection of a variable node column and a check node row indicates a connection between that variable node and check node and provides a permutation for messages between that variable node and check node:

$$H = [ \begin{matrix}0 & a ( 1 , 2 ) & 0 & a ( 1 , 4 ) & a ( 1 , 5 ) & a ( 1 , 6 ) \\ a ( 2 , 1 ) & 0 & a ( 2 , 3 ) & a ( 2 , 4 ) & 0 & a ( 2 , 6 ) \\ a ( 3 , 1 ) & a ( 3 , 2 ) & a ( 3 , 3 ) & 0 & a ( 3 , 5 ) & 0\end{matrix} ] \qquad ( Eq 3 )$$

For example, in some embodiments of a GF(4) decoder with circulant size 4, each Galois field element a(i,j) specifies a shift for the corresponding circulant matrix of 0, 1, 2 or 3.

By providing multiple check nodes 502-506 for the group of variable nodes 510-520, redundancy in error checking is provided, enabling errors to be corrected as well as detected. Each check node 502-506 performs a parity check on bits or symbols passed as messages from its neighboring (or connected) variable nodes. In the example low density parity check code corresponding to the Tanner graph 500 of FIG. 5, check node 502 checks the parity of variable nodes 512, 516, 518 and 520. Values are passed back and forth between connected variable nodes 510-520 and check nodes 502-506 in an iterative process until the low density parity check code converges on a value for the group of data and parity bits in the variable nodes 510-520, or until a maximum number of iterations is reached. For example, variable node 510 passes messages to check nodes 504 and 506, referred to herein as variable node to check node messages or V2C messages. Check node 502 passes messages back to variable nodes 512, 516, 518 and 520, referred to herein as check node to variable node messages or C2V messages. The messages between variable nodes 510-520 and check nodes 502-506 are probabilities or beliefs, thus the low density parity check decoding algorithm is also referred to as a belief propagation algorithm. Each message from a node represents the probability that a bit or symbol has a certain value based on the current value of the node and on previous messages to the node.

A message from a variable node to any particular neighboring check node is computed using any of a number of algorithms based on the current value of the variable node and the last messages to the variable node from neighboring check nodes, except that the last message from that particular check node is omitted from the calculation to prevent positive feedback. Similarly, a message from a check node to any particular neighboring variable node is computed based on the current value of the check node and the last messages to the check node from neighboring variable nodes, except that the last message from that particular variable node is omitted from the calculation to prevent positive feedback. As local decoding iterations are performed in the system, messages pass back and forth between variable nodes 510-520 and check nodes 502-506, with the values in the nodes 502-520 being adjusted based on the messages that are passed, until the values converge and stop changing or until a maximum number of iterations is reached.

Decoder convergence is checked by determining whether the syndrome s=cH^{T} is all zero. The syndrome is a vector of length m, with each bit corresponding to a parity check. A zero bit in a syndrome means the check is satisfied, while a non-zero bit in the syndrome is an unsatisfied check (USC). By definition, a codeword has syndrome s=0. A non-codeword has a non-zero syndrome.

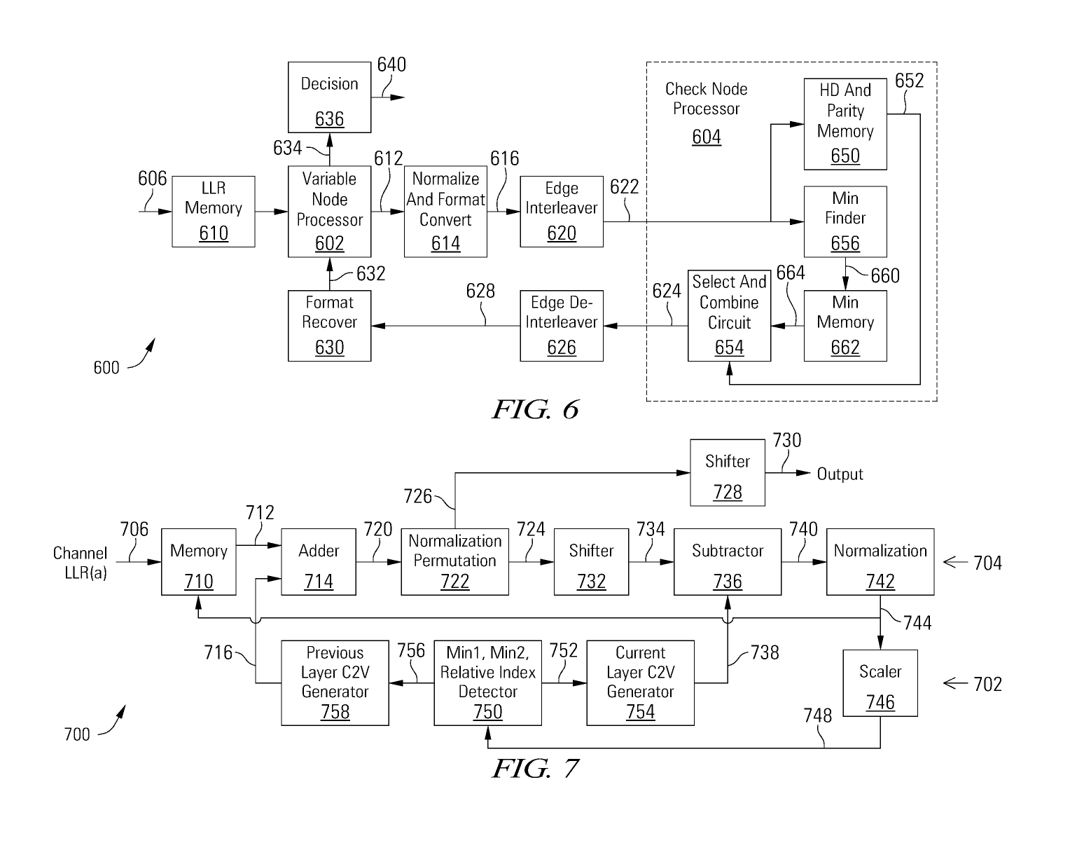

Turning to FIG. 6, in some embodiments, the low density parity check decoder with relative indexing is a non-layer min-sum based decoder 600 in which check nodes calculate a minimum and its index, next minimum, and hard decision value based on incoming variable node to check node messages. The index values reference only non-zero circulants in the H-matrix for the low density parity check code, disregarding zero circulants.

The low density parity check decoder 600 is provided with an input 606, for example containing a hard decision and corresponding LLR values, which are stored in a symbol memory 610. The input 606 is provided to the variable node processor 602 from the symbol memory 610, and the variable node processor 602 updates the perceived value of each symbol based on the value from input 606 and on check node to variable node messages 624 from a check node processor 604. The variable node processor 602 also generates variable node to check node messages 612 or variable node messages for neighboring check nodes.

Check nodes (implemented in check node processor 604) in low density parity check decoder 600 receive incoming messages from connected or neighboring variable nodes (implemented in variable node processor 602) and generate outgoing messages to each neighboring variable node to implement the H-matrix or parity check matrix for the low density parity check code, an example of which is graphically illustrated in the Tanner graph of FIG. 5. Variable node to check node messages flow from variable nodes to check nodes, and check node to variable node messages flow from check nodes to variable nodes. The check node is updated in the check node processor 604 based on multiple variable node to check node messages to generate an individualized check node to variable node message with for each neighboring variable node.

In various embodiments of low density parity check decoders with relative indexing, the variable node processor 602 and check node processor 604 can each be unitary, discrete components, or their functions may be distributed and intermixed in multiple components. The terms variable node processor and check node processor are therefore not limited to two discrete processing components, but apply generally to any components or combinations of components in a low density parity check decoder that update variable node values and generate variable node to check node messages for variable node processing, and that perform check node constraint calculations and generate check node to variable node messages for check node processing.

Both variable node to check node and check node to variable node messages in this embodiment are vectors, each including a number of sub-messages with LLR values. Each variable node to check node message vector from a particular variable node contains sub-messages corresponding to each symbol in the Galois Field, with each sub-message giving the likelihood that the variable node contains that particular symbol. For example, given a Galois Field GF(q) with q elements, variable node to check node and check node to variable node messages will include at least q sub-messages representing the likelihood for each symbol in the field.

Generally, the check node to variable node vector message from a check node to a variable node contains the probabilities for each symbol d in the Galois Field that the destination variable node contains that symbol d, based on the prior round variable node to check node messages from neighboring variable nodes other than the destination variable node. The inputs from neighboring variable nodes used for a check node to generate the check node to variable node message for a particular neighboring variable node are referred to as extrinsic inputs and include the prior round variable node to check node messages from all neighboring variable nodes except the particular neighboring variable node for which the check node to variable node message is being prepared, in order to avoid positive feedback. The check node update thus involves preparing a different check node to variable node message for each neighboring variable node, using the different set of extrinsic inputs for each message based on the destination variable node.

In the min-sum based decoding disclosed herein, the check nodes calculate the minimum sub-message min₁(d), the index idx(d) of min₁(d), and the next minimum or sub-minimum sub-message min₂(d), or minimum of all sub-messages excluding min₁(d) for each nonzero symbol d in the Galois Field based on all extrinsic variable node to check node messages from neighboring variable nodes. In other words, the sub-messages for a particular symbol d are gathered from messages from all extrinsic inputs, and the min₁(d), idx(d) and min₂(d) are calculated based on the gathered sub-messages for that symbol d, where, again, the indexes reference only non-zero circulants. For a Galois Field with q symbols, a check node update involves calculating the min₁(d), idx(d) and min₂(d) sub-message for each of the q-1 non-zero symbols in the field except the most likely symbol.

The variable node to check node message vectors 612 from the variable node processor 602 are provided to a message format converter 614 which converts the format of variable node to check node message vectors 612 to a format consisting of two parts, the most likely symbol, and the LLR of other symbols, normalized to the most likely symbol, yielding normalized variable node to check node message vectors 616 in the second format. Message normalization in the message format converter 614 is performed with respect to the most likely symbol. Thus, the variable node to check node and check node to variable node vector format includes two parts, an identification of the most likely symbol and the LLR for the other q-1 symbols, since the most likely symbol has LLR equal to 0 after normalization. The normalized variable node to check node message vectors 616 are provided to an edge interleaver 620 which shuffles messages on the boundaries at message edges, randomizing noise and breaking dependencies between messages. The interleaved normalized variable node to check node message vectors 622 are provided to the check node processor 604, which generates check node to variable node messages 624 for each neighboring variable node processor based on extrinsic variable node to check node messages from other neighboring variable node processors.

The check node to variable node messages 624 are provided to an edge de-interleaver 626, which reverses the process of the edge interleaver 620, and then to a format recovery circuit 630, which converts message vectors from the second, normalized format to the first message vector format of the variable node processor 602, reversing the process of the message format converter 614. The resulting first format check node to variable node messages 632 are provided to the variable node processor 602 for use in updating perceived LLR values in variable nodes. In other embodiments, the variable node processor 602 is adapted to operate directly with message vectors of the second, normalized format. In these embodiments, the message format converter 614 and format recovery circuit 630 are omitted.

When the values in the min-sum based low density parity check decoder 600 converge and stabilize, or when a limit is reached on the number of local iterations, the variable node processor 602 provides the total LLR Sₙ(a) 634 to a decision circuit 636 to generate a hard decision 640 based on the argminₐ of the total LLR Sₙ(a).

The check node processor 604 includes a hard decision and parity memory circuit 650 that processes the interleaved normalized variable node to check node message vectors 622 to provide the most likely symbol 652 to a select and combine circuit 654. The check node processor 604 also includes a min finder 656 that calculates the min₁(d), idx(d) and min₂(d) sub-messages 660 for each of the q symbols in the Galois Field and stores them in a min memory 662. The stored min₁(d), idx(d) and min₂(d) sub-messages 664 are provided by min memory 662 to the select and combine circuit 654. The select and combine circuit 654 combines the min₁(4 idx(d) and min₂(d) sub-messages 664 and the most likely symbol 652 to generate the check node to variable node messages 624.

The message vector format conversion performed by message format converter 614 on variable node to check node message vectors 612 is reversed by format recovery circuit 630, providing check node to variable node messages 632 to variable node processor 602 in the format used by the variable node processor 602.

Turning to FIG. 7, a low density parity check layer decoder 700 with relative indexing is depicted in accordance with some embodiments of the present invention. The low density parity check decoder 700 generates check node to variable node messages from a min-sum based check node processor 702 to a variable node processor 704, and may be either a binary or multi-level decoder. Incoming LLR values for data to be decoded are received at input 706 and stored in a memory 710. The memory 710 stores soft LLR input values from the input 706 and Q values of each symbol, representing the likelihood that an input symbol has the value of each element of the Galois Field. In some embodiments of a GF(4) low density parity check decoder, the Q values consist of one hard decision and three soft LLR values, or four soft LLR values in an equivalent but alternative format.

The memory 710 yields stored Q values 712 or Qₙ(a) for the layer previous to the layer currently being processed, also referred to herein as the previous layer and the connected layer. An adder 714 adds the Q values 712 to previous layer check node to variable node messages 716 or R_{1,n}(a) in array fashion to produce S messages 720 or Sₙ(a) containing total soft LLR values for the previous layer. Again, columns in the H matrix represent variable nodes, and by adding all the non-zero entries in a column, the connected variable nodes are added to yield the input to a check node.

The S messages 720 are provided to a normalization and permutation circuit 722, which converts the format of the S messages 720 from four soft LLR values to the equivalent content but different format of one hard decision and three soft LLR values (for a GF(4) embodiment), and which applies a permutation to rearrange the variable node updated values to prepare for the check node update and to apply the permutations specified by the non-zero elements of the H matrix. For example, in a GF(4) embodiment, the four elements 0-3 of the Galois Field are 0, 1, α, α². The permutation applied by normalization and permutation circuit 722 is a multiplication in the Galois Field. Element 2 (α) multiplied by element 1 (1) equals α×1 or α, which is element 2. Similarly, element 2×2=α×α=α², which is element 3. Element 2×3=α×α²=1, which is element 1. Thus, element 2 multiplied by 1, 2 and 3 results in elements 2, 3, and 1, which are permutations of elements 1, 2 and 3. The normalization and permutation circuit 722 yields P messages 724 or Pₙ(a) for the previous layer.

The P messages 724 from the normalization and permutation circuit 722 are provided to a shifter 732, a cyclic shifter or barrel shifter which shifts the symbol values in the normalized LLR P messages 724 to generate the next circulant sub-matrix, yielding current layer P messages 734 which contain the total soft LLR values of the current layer.

The current layer P messages 734 are provided to a subtractor 736 which subtracts the current layer check node to variable node messages 738, or R_{2,n}(a), from the current layer P messages 734, yielding D messages 740, or Dₙ(a). The current layer check node to variable node messages 738 are old values for the current layer, generated during a previous decoding iteration. Generally, the vector message from a check node to a variable node contains the probabilities for each symbol d in the Galois Field that the destination variable node contains that symbol d, based on the prior round variable node to check node messages from neighboring variable nodes other than the destination variable node. The inputs from neighboring variable nodes used in a check node to generate the check node to variable node message for a particular neighboring variable node are referred to as extrinsic inputs and include the prior round variable node to check node messages from all neighboring variable nodes except the particular neighboring variable node for which the check node to variable node message is being prepared, in order to avoid positive feedback. The check node prepares a different check node to variable node message for each neighboring variable node, using the different set of extrinsic inputs for each message based on the destination variable node. Subtracting the current layer check node to variable node messages 738 from an earlier iteration removes the intrinsic input, leaving only the extrinsic inputs to generate a check node to variable node message for a variable node.

D messages 740 are provided to a normalization circuit 742 which converts the format of the D messages 740 from four soft LLR values to the equivalent content but different format of one hard decision and three soft LLR values, yielding new Q messages 744, or Q_{2,n}(a), also referred to as variable node to check node messages, for the current layer. The Q messages 744 are stored in memory 710, overwriting previous channel or calculated values for the current layer, and are also provided to a scaler 746 which scales the Q messages 744 to yield scaled variable node to check node messages 748, or T_{2,n}(a).

Variable node to check node messages 748 are provided to a min finder circuit 750 which calculates the minimum value min₁(d), its index idx(d), and the second or next minimum value min₂(d). Again, the index idx(d) applies only to non-zero circulants, with zero circulants being disregarded. The min finder circuit 750 also calculates the signs of the variable node to check node messages 748 and tracks the sign value of each non-zero element of the H matrix and the cumulative sign for the current layer. The min finder circuit 750 yields the current layer minimum, next minimum and both index values with the sign values 752 to a current layer check node to variable node message generator 754, which calculates the current layer check node to variable node messages 738, or R_{2,n}(a). The min finder circuit 750 also yields the previous layer minimum, next minimum and both index values with the sign values 756 to a previous layer check node to variable node message generator 758, which calculates the previous layer check node to variable node messages 716, or R_{1,n}(a). The current layer check node to variable node message generator 754 and previous layer check node to variable node message generator 758 generate the check node to variable node messages or R messages 738 and 716 based on the final state and current column index of the symbol. If the current column index is equal to the index of the minimum value, then the value of R is the second minimum value. Otherwise, the value of R is the minimum value of that layer. The sign of R is the XOR of the cumulative sign and the current sign of the symbol.

The variable node processor 704 and the check node unit 702 thus operate together to perform layered decoding of non-binary or multi-level data. The variable node processor 704 generates variable node to check node messages and calculates perceived values based on check node to variable node messages. The check node unit 702 generates check node to variable node messages and calculates checksums based on variable node to check node messages, using a min finder circuit 750 operable to identify a minimum, a next minimum and an index of each in the variable node to check node messages.

Normalization and permutation circuit 722 also yields soft LLR values 726 which are provided to a cyclic shifter 728. Cyclic shifter 728 rearranges the soft LLR values 726 to column order, performs a barrel shift which shifts the normalized soft LLR values 726 from the previous layer to the current layer, and which yields hard decisions 730 or aₙ*, calculated as argminₐ Sₙ(a).

In low density parity check decoders in which the min₁ index idx can reference every column in the H-matrix, meaning that every column in the H-matrix is enumerated by the index value, whether it contains a non-zero circulant for a particular row or not, the number of bits required to store the index is based on the number of columns in the H-matrix. However, because the low density parity check code matrix or H-matrix is sparse, there are many more zero circulants than non-zero circulants. The row weight of a quasi-cyclic code is much less than the number of circulant columns. By indexing only the non-zero circulants of each row or layer in the low density parity check decoder with relative indexing, the number of bits required to store the index is reduced and a variety of operations in the decoder are simplified. The term “relative indexing” is thus used herein to refer to indexing only the non-zero circulants of each row or layer, so the index number is relative to non-zero circulants in the row, rather than to the column number in the row. The number of flip-flops or other storage devices saved by relative indexing in some non-binary min-sum based decoder embodiments can be calculated as the number of check nodes in the H-matrix multiplied by the reduction in the number of bits required to store the index, multiplied by the number of LLR values for each variable node. Flip-flops, for example, are relatively expensive hardware devices because they use clock tree insertion and scan chain insertion, requiring more area and devices than combination logic. The reduction of thousands of flip-flops from the decoder thus greatly reduces the area and power consumption of the decoder.

An example of layer decoding with relative indexing according to some embodiments can be presented with reference to FIG. 8. A simple H-matrix 800 is shown, in which non-zero circulants (e.g., 802, 804, 806, 808) are denoted by letters. When processing a particular layer (e.g., 810) in a layer decoder, for each circulant being processed (e.g., 806, 808), the variable node to check node messages for the last layer are read. For example, when processing circulants N 806 and I 808 in the third layer 810, the decoder reads the Q information (e.g., 712) as it was updated by circulants A 802 and B 804 in the previously processed layer 812 for the columns 814, 816 containing the circulants N 806 and I 808 being processed. In other words, circulants A 802 and B 804 are in the last layer 812 processed in the columns 814, 816 containing the circulants N 806 and I 808. The latest R information (e.g., 716) will be added, which is the min₁, min₂ generated R information for the previous layer 812, yielding the total LLR P information (e.g., 720). The total LLR P information is used to perform the parity check, and is also shifted to be aligned with circulants N 806 and I 808 in the current layer 810. The R information (e.g., 738) in the check node to variable node messages for the current layer is subtracted from the current layer P information (e.g., 734) to yield the updated variable node to check node message Q (e.g., 744). Once each layer in the H matrix has been processed, a local decoding iteration has been completed.

During the generation of the new check node to variable node message (e.g., 738) and old check node to variable node message (e.g., 716), the current circulant index is compared with the stored min₁ index, and if it is equal to the min₁ index, the check node to variable node message is generated using min₂, and if the current circulant index is not equal to the min₁ index, the check node to variable node message is generated using min₁. Relative indexing is applied in these index values, so the possible index values refer only to non-zero circulants in the H matrix, disregarding zero circulants.

Relative indexing can be used in any element of the decoder that retrieves circulant information. For example, in some embodiments, as in the low density parity check layer decoder 700 of FIG. 7, the min-sum based check node processor 702 applies relative indexing in a number of locations, such as, but not limited to, the min finder circuit 750, the current layer check node to variable node message generator 754 and the previous layer check node to variable node message generator 758. The min finder circuit 750 uses the relative indexing when generating and storing the min₁ index. The current layer check node to variable node message generator 754 uses the relative indexing when generating the C2V old R values for the current layer. The previous layer check node to variable node message generator 758 uses the relative indexing when generating the C2V new R values for the previous layer.

The relative indexing can be applied in a number of different manner in various embodiments of the invention. In some embodiments, the spatial index of non-zero circulants in a given layer is used as the relative index for the min₁ value. In some other embodiments, the decoding cycle index for the previous layer is used as the relative index for the min₁ value of a circulant.

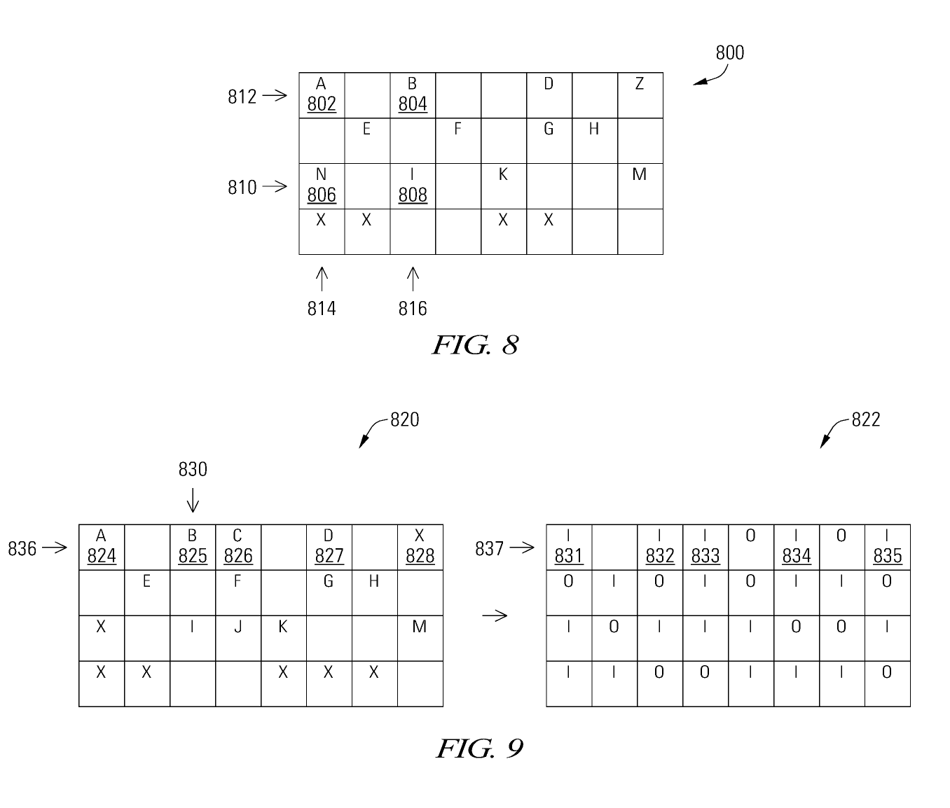

Turning to FIG. 9, an H matrix 820 with lettered non-zero circulant sub-matrices is depicted which can be decoded by a quasi-cyclic low density parity check layer decoder with relative indexing, along with a corresponding weight matrix 822 indicating non-zero circulant locations, in accordance with some embodiments of the present invention. In this embodiment, the non-zero circulant index is used for the relative index, and is calculated using a memory in the decoder such as, but not limited to, a Read Only Memory (ROM) containing the weight matrix 822. For example, in the H matrix 820 of FIG. 9, only the lettered circulants (e.g., 824, 825, 826, 827, 828 . . . ) are non-zero, and the empty circulants have zero values. In the corresponding memory 822, a bit is provided for each circulant in the H matrix 820, with a 1 (e.g., 831, 832, 833, 834, 835) indicating that the corresponding circulants (e.g., 824, 825, 826, 827, 828 . . . ) are non-zero, and with a 0 indicating that the corresponding circulant has a zero value.

During decoding in the layer decoder, the variable node processor performs updates of the variable node values based on check node to variable node messages, subtracting and adding as disclosed above. In some embodiments, the variable node processor processes two non-zero circulants per clock cycle, taking their full column indexes and reading the row of the weight matrix 822 to calculate the relative non-zero circulant index. For example, considering circulant B 825 in the first layer 836, in the third column 830 of the H matrix 820, the variable node processor reads the first row 837 of the weight matrix 822, a=[1 0 1 1 0 1 0 1], and sums the weights up through the full column index of circulant B 825, or sum(a[0:2]), yielding 2, which is the relative index or spatial index of non-zero circulant B 825.

During the check node processing in the decoder, the variable node to check node messages are compared to select the minimum value min₁(d), its relative index idx(d), and the second or next minimum value min₂(d). For example, if the min₁ for a check node is from circulant B 825, its relative index idx is 2. If the min₁ for another check node is from circulant D 827, its relative index idx is 4, based on sum(a[0:5]). The check node to variable node message generators 754, 758 also perform comparisons using relative indexes when generating the check node to variable node messages 738, 716, saving memory elements in the check node processor by using the relative indexes.

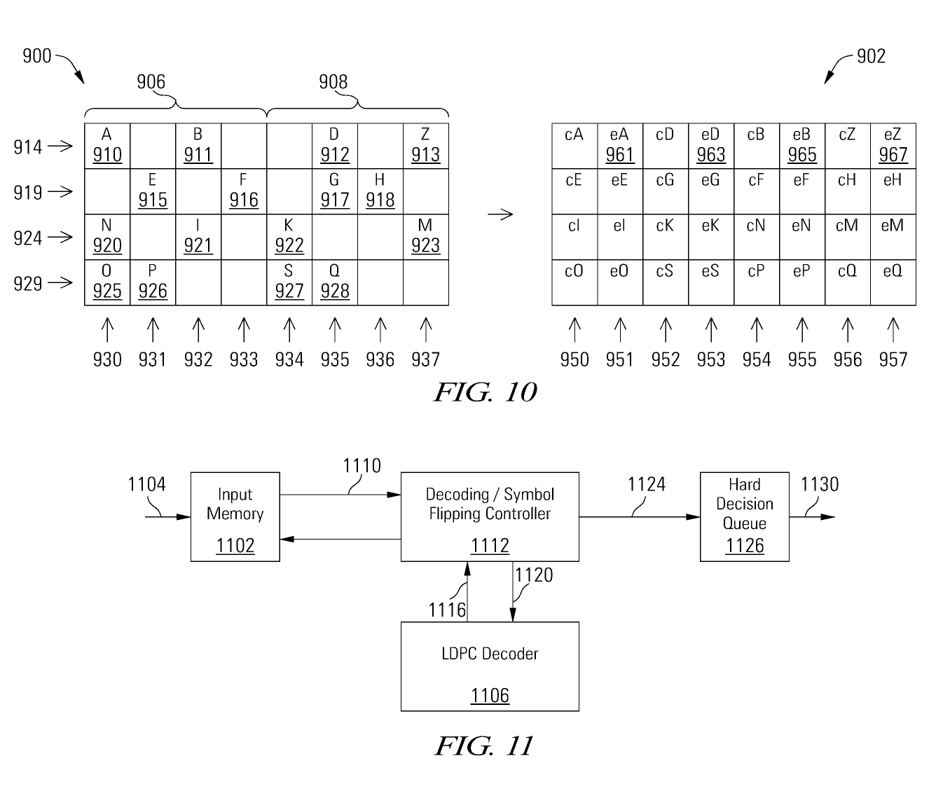

Turning to FIG. 10, another embodiment is disclosed in which the decoding cycle index for the previous layer is used as the relative index for the min₁ value of a circulant. An H matrix 900 is depicted with a corresponding decoding instruction set 902 which can used for decoding in a quasi-cyclic low density parity check layer decoder with relative indexing in accordance with some embodiments of the present invention. In this embodiment, the relative index is not based on the physical order of non-zero circulants from left to right or right to left, it is based on the decoding order of the last layer. The relative index based on decoding order for each non-zero circulant is pre-calculated and stored in the instruction set 902. In some cases, the relative index is stored as additional bits in extended columns 951, 953, 955, 957, adding relative index information to the other instruction set information stored in content columns 950, 952, 954, 956. The relative index can then be retrieved from the additional bits during decoding to identify non-zero circulants, along with the other information in content columns 950, 952, 954, 956 such as, but not limited to, the entry value for the non-zero circulant, the shift needing to be applied to the circulant during decoding, whether it is the end of the layer, etc.

In the example embodiment of FIG. 10, the H matrix includes four layers 914, 919, 924, 929, and is divided into two groups 906, 908 of four columns each, with columns 930, 931, 932, 933 in group 906 and columns 934, 935, 936, 937 in group 908. During each clock cycle, the decoder can process two non-zero circulants, taking one from each group 906, 908. Thus, to process a layer (e.g., 914), the decoder processes circulants for two clock cycles. In this example embodiment, a decoding order of AD→BZ→EG→FH→IK→NM→OS→PQ is assumed, with two non-zero circulants being processed during each successive clock cycle, and with the arrows indicating a change in clock cycle. During the first clock cycle, non-zero circulants A 910 and D 912 are processed, and in the second clock cycle, non-zero circulants B 911 and Z 913 are processed. During the third clock cycle, non-zero circulants E 915 and G 917 are processed, and in the fourth clock cycle, non-zero circulants F 916 and H 918 are processed. During the fifth clock cycle, non-zero circulants I 921 and K 922 are processed, and in the sixth clock cycle, non-zero circulants N 910 and M 923 are processed. During the seventh clock cycle, non-zero circulants O 925 and S 927 are processed, and in the eighth clock cycle, non-zero circulants P 926 and Q 928 are processed.

The extended bits in the instruction set 902 are generated based on the last layer's decoding order of each non-zero circulant. In other words, when decoding a particular circulant, the circulant in the last layer of the same column is accessed, and the decoding order of that circulant in the last layer is stored for the circulant being decoded. For example, when decoding circulant A 910, the last layer is the fourth layer 929 containing circulant O 925. For circulant D 912, the last layer is the fourth layer 929 containing circulant Q 928. For circulant B 911, the last layer is the third layer 924 containing circulant I 921. For circulant Z 913, the last layer is the third layer 924 containing circulant M 923. When generating the extended bits for each circulant, the decoding order for the corresponding circulant in the last layer is considered. Because each layer is decoded in two clock cycles, the decoding cycle index for the layer is 0, 1, with two circulants processed at each clock cycle.

For example, circulant O 925 is the last layer circulant for circulant A 910, and circulant O 925 is decoded in the first clock cycle for its layer 929, thus the extended bits eA 961 for circulant A 910 contain value 0, the decoding cycle index for the first clock cycle of layer 929. Circulant Q 928 is the last layer circulant for circulant D 912, and circulant Q 928 is decoded in the second clock cycle for its layer 929, thus the extended bits eD 963 for circulant D 912 contain value 1, the decoding cycle index for the second clock cycle of layer 929. Circulant I 921 is the last layer circulant for circulant B 911, and circulant I 921 is decoded in the first clock cycle for its layer 924, thus the extended bits eB 965 for circulant B 911 contain value 0, the decoding cycle index for the first clock cycle of layer 924. Circulant M 923 is the last layer circulant for circulant Z 913, and circulant M 923 is decoded in the second clock cycle for its layer 924, thus the extended bits eZ 967 for circulant Z 913 contain value 1, the decoding cycle index for the second clock cycle of layer 924. In some other embodiments with more non-zero circulants per layer than 4, the decoding cycle index can be higher than for each layer. For example, in a decoder with an H-matrix with 6 non-zero circulants per layer, and being able to process 2 circulants per clock cycle, it would take three clock cycles to process the circulants, 0, 1 and 2.

Thus, a bridge is built between the decoding order and the decoding cycle index for the previous layer of each circulant, which is used as the relative index for the min₁ value of the circulant. Notably, this embodiment of the relative index still refers only to non-zero circulants, but also gives the decoding cycle index of the circulants last layer. Although some bits are added to the instruction set to refer to the decoding cycle index for the last layer for a circulant, overall the number of memory elements is reduced with the relative indexing. Embodiments such as in this example which employ out-of-order processing avoid idle cycles during decoding. However, when the code is designed so that the decoding order of each layer is the same and can be decoded with in-order-processing, the decoding order can be calculated on the fly without adding the additional bits to the instruction set.

Relative indexing in a low density parity check decoder can also simplify other operations, such as targeted symbol flipping used to correct errors when data fails to converge in the decoder. In targeted symbol flipping, the values of variable nodes connected to check nodes with unsatisfied parity checks can be forcibly changed, and the decoding is then repeated. Rather than scanning the instruction set to identify variable nodes connected to unsatisfied check nodes, the decoder can directly calculate indexes of variable nodes connected to unsatisfied check nodes. In general, the decoder calculates the layer and the symbol index of only the check nodes with unsatisfied parity checks, identified by the decoder when decoding fails. The decoder finds the stored relative index for the min₁ value for the unsatisfied check, then directly calculates the convergence instruction row address. The decoder reads the convergence instruction at the calculated address and obtains the connected layers indexes, which are all treated as unsatisfied check nodes. The decoder then finds the variable nodes connected to the unsatisfied check nodes.

In some embodiments, the targeted symbol flipping instruction set address can be calculated for a target non-zero circulant based on the relative index for the min₁ value by calculating the total number of non-zero circulants in layers before the layer containing the target circulant, and the total number of non-zero circulants before the target circulant in the layer containing the target circulant, and adding the two to get the total number of non-zero circulants before the target circulant. If four circulants can be stored at each memory location, the offset address of the target circulant is calculated as the total number of preceding non-zero circulants, divided by 4 and rounded down with the Floor operation, plus 1. The absolute address can then be calculated as the start address in memory for the circulants, plus the offset address, minus 1.

Such a low density parity check decoder with relative indexing-based targeted symbol flipping is depicted in FIG. 11 according to some embodiments of the invention. An input memory 1102 stores a soft data decoder input 1104, or LLR data of unconverged component codewords to be decoded in a symbol flipping decoder 1106. The unconverged LLR data 1110 from the input memory 1102 are provided to a decoding/symbol flipping controller 1112 which stores component codewords as they are decoded by symbol flipping decoder 1106 and in which symbols are flipped during symbol flipping operations. In some stages of operation, such as during symbol flipping operations, the decoding/symbol flipping controller 1112 sends requests 1114 for unconverged LLR data 1110 from the input memory 1102. Modified LLR data and hard decision (HD) data 1116 is transferred between the decoding/symbol flipping controller 1112 and the symbol flipping LDPC decoder 1106 during decoding operations, with the LLR values updated during local decoding iterations in the symbol flipping LDPC decoder 1106. The symbol flipping decoder 1106 performs variable node and check node updates to calculate the new values for the modified LLR data 1116, using relative indexes. The symbol flipping decoder 1106 also performs parity checks on the modified LLR data 1116, determining which parity checks are not satisfied and yielding a pool or list of unsatisfied checks (USC). The symbol flipping decoder 1106 and the decoding/symbol flipping controller 1112 operate together, passing a list of unsatisfied checks 1116 and addresses 1120 of symbols to be flipped to control the symbol flipping operation. The symbol flipping decoder 1106 and the decoding/symbol flipping controller 1112 identify the circulants of symbols to be flipped using relative indexes as disclosed above.

Hard decisions 1124 for the component codewords generated by the symbol flipping decoder 1106 in decoding operations and symbol flipping operations are transferred from the decoding/symbol flipping controller 1112 to a hard decision queue 1126, which yields output hard decisions 1130.

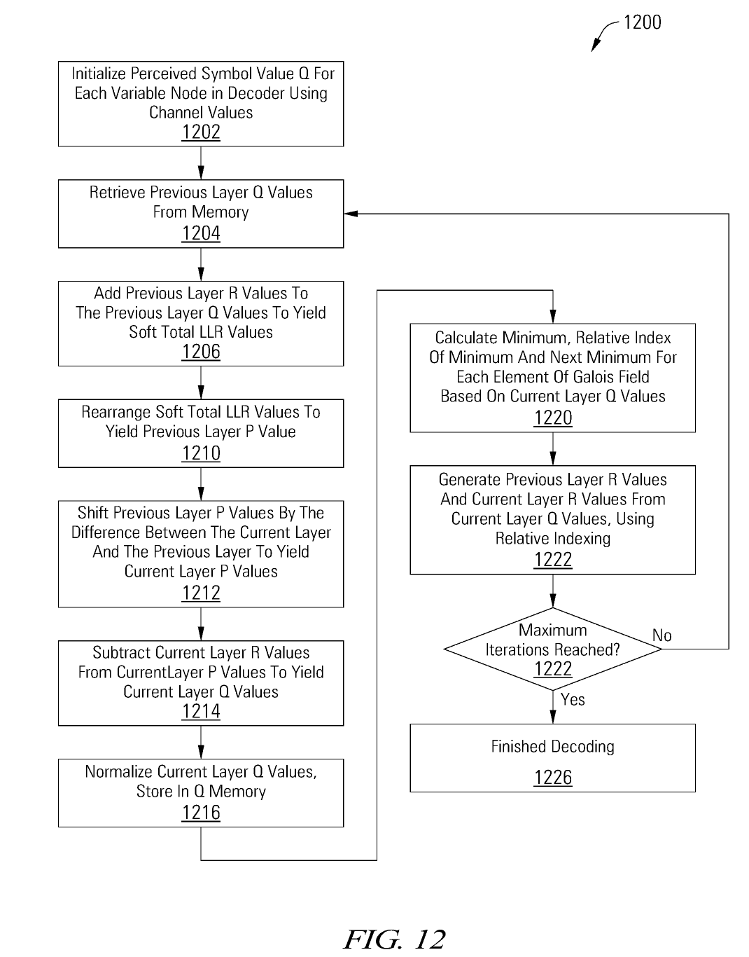

Turning to FIG. 12, a flow diagram 1200 is depicted of an operation to decode data in a low density parity check layer decoder with relative indexing in accordance with some embodiments of the present invention. Following flow diagram 1200, the perceived symbol value Q is initialized for each variable node in decoder using channel values. (Block 1202) The previous layer Q values are retrieved from memory. (Block 1204) The previous layer R values are added to the previous layer Q values in the previously determined circulant processing order to yield soft total LLR values. (Block 1206) The soft total LLR values are rearranged to yield previous layer R values. (Block 1210) The previous layer R values are shifted by the difference between the current layer and the previous layer to yield current layer P values. (Block 1212) The current layer R values are subtracted from the current layer P values to yield current layer Q values. (Block 1214) The current layer Q values are normalized and stored in the Q memory. (Block 1216) The minimum, relative index of the minimum and the next minimum are calculated for each element of the Galois field based on current layer Q values. (Block 1220) Previous layer R values and current layer R values are generated from the minimum, relative index and next minimum, using relative indexing. (Block 1222) Once each layer in the H matrix has been processed, a determination is made as to whether the maximum number of iterations has been reached. (Block 1224) If so, decoding is finished. (Block 1226) Otherwise, another decoding iteration is performed. (Block 1204)

It should be noted that the various blocks discussed in the above application may be implemented in integrated circuits along with other functionality. Such integrated circuits may include all of the functions of a given block, system or circuit, or a subset of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some such cases, the entire system, block or circuit may be implemented using its software or firmware equivalent. In other cases, the one part of a given system, block or circuit may be implemented in software or firmware, while other parts are implemented in hardware.

In conclusion, embodiments of the present invention provide novel systems, devices, methods and arrangements for a low density parity check decoder with relative indexing. While detailed descriptions of one or more embodiments of the invention have been given above, various alternatives, modifications, and equivalents will be apparent to those skilled in the art without varying from the spirit of the invention. Therefore, the above description should not be taken as limiting the scope of embodiments of the invention which are encompassed by the appended claims.

What is claimed is:

1. An apparatus for low density parity check decoding comprising:
a variable node processor, wherein the variable node processor is operable to generate variable node to check node messages and to update variable node values based on check node to variable node messages; and
a check node processor, wherein the check node processor is operable to generate the check node to variable node messages based on the variable node to check node messages, wherein the variable node processor and the check node processor comprise a quasi-cyclic decoder with relative indexes that refer to non-zero circulants.

2. The apparatus of claim 1, wherein the check node processor comprises:
a minimum and next minimum finder circuit operable to process a plurality of sub-messages in each of a plurality of the variable node to check node messages to identify a minimum message, a relative index of the minimum message, and a next minimum message; and
at least one message generator operable to combine an output of the minimum and next minimum finder circuit to generate the check node to variable node messages.

3. The apparatus of claim 1, wherein the relative indexes comprise a spatial index of the non-zero circulants in a parity check matrix.

4. The apparatus of claim 3, further comprising a memory operable to store a weight matrix indicating locations of the non-zero circulants in the parity check matrix.

5. The apparatus of claim 4, wherein the check node processor is operable to calculate the relative indexes by summing weights from the weight matrix in the memory.

6. The apparatus of claim 1, wherein the relative indexes comprise a decoding cycle index for a previous layer of each of the non-zero circulants.

7. The apparatus of claim 6, further comprising an instruction set memory operable to store the decoding cycle index.

8. The apparatus of claim 7, wherein the decoding cycle index is based on a decoding order of a last layer for each of the non-zero circulants.

9. The apparatus of claim 1, wherein the variable node processor and the check node processor comprise a low density parity check layer decoder.

10. The apparatus of claim 1, further comprising a symbol flipping controller operable to identify symbols to be flipped corresponding to unsatisfied parity checks.

11. The apparatus of claim 10, wherein an address of the circulant of each of the symbols to be flipped is calculated using the relative indexes.

12. The apparatus of claim 1, wherein the apparatus is implemented as an integrated circuit.

13. The apparatus of claim 1, wherein the apparatus is incorporated in a storage device.

14. The apparatus of claim 1, wherein the apparatus is incorporated in a transmission system.

15. A method for low density parity check decoding, comprising:
generating a variable node to check node message in a variable node processor based at least in part on a plurality of check node to variable node messages;
calculating a minimum, index of minimum and sub-minimum value in a check node processor for each element in a Galois Field from each of the plurality of variable node to check node messages; and
generating a check node to variable node message in the check node processor by combining the minimum, index of minimum and sub-minimum values, wherein the indexes of the minimums comprise relative indexes that refer only to non-zero circulants in a parity check matrix.

16. The method of claim 15, wherein the relative indexes comprise spatial indexes of the non-zero circulants.

17. The method of claim 15, wherein the relative indexes comprise decoding cycle indexes of a circulant in a last layer for each of the non-zero circulants.

18. The method of claim 15, further comprising performing targeted symbol flipping of symbols associated with unsatisfied check nodes.

19. The method of claim 18, further comprising calculating addresses of circulants corresponding to the symbols to be flipped based on the relative indexes.

20. A storage system comprising:
a storage medium;
a head assembly disposed in relation to the storage medium and operable to provide a sensed signal corresponding to information on the storage medium; and
an analog to digital converter circuit operable to sample an analog signal derived from the sensed signal to yield a series of digital samples; and
a quasi-cyclic low density parity check decoder with relative indexing operable to decode data in a signal derived from an output of the analog to digital converter circuit, comprising:
a variable node processor, wherein the variable node processor is operable to generate variable node to check node messages and to update variable node values based on check node to variable node messages; and
a check node processor, wherein the check node processor is operable to generate the check node to variable node messages based on the variable node to check node messages, using relative indexes that refer to only non-zero circulants in a parity check matrix.
